(19) United States
(12) Patent Application Publication
(10) Pub. No.: US 2019/0176657 A1
(43) Pub. Date: Jun. 13, 2019

(54) ESTIMATION OF SOC OF A LEAD-ACID BATTERY

(71) Applicant: MAHINDRA & MAHINDRA LIMITED, Tamilnadu (IN)

(72) Inventors: Nabal Kishore PANDEY, Tamilnadu (IN); Satish THIMMALAPURA, Tamilnadu (IN); Kannan SUBRAMANIAN, Tamilnadu (IN); Kumarprasad TELIKEPALLI, Tamilnadu (IN)

(73) Assignee: MAHINDRA & MAHINDRA LIMITED, Tamilnadu (IN)

(21) Appl. No.: 16/321,937

(22) PCT Filed: Jul. 26, 2017
(86) PCT No.: PCT/IN2017/050307

§ 371 Date: Jan. 30, 2019

(30) Foreign Application Priority Data
Aug. 5, 2016 (IN) 201641026864

(51) Int. Cl. B60L 58/12; G01R 31/382; G01R 31/387; H02J 7/14; H02J 7/00; H01M 10/06; B60L 50/50

(52) U.S. Cl. CPC B60L 58/12; G01R 31/382; G01R 31/387; B60L 50/50; H02J 7/0021; H01M 10/06; H02J 7/1461

(57) ABSTRACT

Estimation of SOC of a lead-acid battery. Embodiments herein disclose methods and systems for determining State of Charge (SOC) of a lead acid battery in a vehicle. Embodiments herein disclose methods and systems for determining State of Charge (SOC) of a lead acid battery in a vehicle using discharge and charge correction factors. Embodiments herein disclose methods and systems for determining State of Charge (SOC) of a lead acid battery in a vehicle using a master OCV table based SOC estimation (SOC_{OCV}) after the vehicle has been powered off, and a current throughput based SOC estimation (SOC_{EST}) based on coulomb count integration (amp-second (As) integration) when the vehicle is operational. Embodiments herein disclose methods and systems for determining State of Charge (SOC) of a lead acid battery in a vehicle considering ageing of the battery and temperature.

### CROSS REFERENCE TO RELATED APPLICATION

This application is based on and derives the benefit of Indian Provisional Application 201641026864, the contents of which are incorporated herein by reference.

### FIELD OF INVENTION

Embodiments herein relate to vehicle systems, and more particularly to lead acid batteries in vehicles.

### BACKGROUND OF INVENTION

In today's automotive scenario, when emission control and dependence of conventional fossil fuel are seen as bigger challenges, a variety of propulsion technologies are being considered to power vehicles. The increasing demand to improve fuel economy and reduce emissions in present vehicles calls for a big push towards powertrain electrification (development of hybrid and electric vehicle).

Lead-acid batteries have been widely used in the automotive industry for starting-lighting-ignition (SLI) applications. But they are typically used as backup energy storage for powering vehicle ECU's during conventional engine off condition and for engine cranking and only add weight to the conventional powertrain during normal running. For optimization of lead acid battery system, it is required to increase the usage (battery cycling) of the battery during normal vehicle running conditions.

Typical applications wherein these batteries are being used are stop start applications and low voltage hybrid vehicle applications. In the stop start application, the engine can be automatically stopped and re-started which typically occurs at traffic signals. This application avoids unnecessary idling of vehicle, hence saving fuel. Low voltage battery systems (lead acid battery based systems with management systems) are being used as cranking device during vehicle re-start. In the low voltage hybrid vehicle application with an electric machine (which can act as alternator and motor) using low voltage battery, hybrid function (torque assist, brake energy recovery) can be achieved. This helps in supporting engine during acceleration and recovering braking energy and hence increasing the overall efficiency of the system.

Both the above said applications, as compared to standard vehicles driven by an ICE (Internal Combustion Engine), bring in improved fuel economy and consequently reduced emissions. For efficient operation, a lead-acid battery needs to operate near to its optimal SOC to maximize its discharge, charge power capabilities and defined life.

Determination of state of charge (SOC) of a lead acid system is a challenging task, as discharge and charge characteristics of a lead-acid battery system are not symmetric. The discharge battery resistance is typically lower than the charge battery resistance. Direct prediction of SOC based on voltage and throughput is not straightforward.

### OBJECT OF INVENTION

The principal object of embodiments as disclosed herein is to provide methods and systems for determining State of Charge (SOC) of a lead acid battery in a vehicle.

Another object of embodiments as disclosed herein is to provide methods and systems for determining State of Charge (SOC) of a lead acid battery in a vehicle using discharge and charge correction factors.

Another object of embodiments as disclosed herein is to provide methods and systems for determining State of Charge (SOC) of a lead acid battery in a vehicle using a master OCV table based SOC estimation (SOC_{OCV}) after the vehicle has been powered off, and a current throughput based SOC estimation (SOC_{EST}) based on coulomb count integration (amp-second (As) integration) when the vehicle is operational.

Another object of embodiments as disclosed herein is to provide methods and systems for determining State of Charge (SOC) of a lead acid battery in a vehicle considering ageing of the battery and temperature.

### BRIEF DESCRIPTION OF FIGURES

This invention is illustrated in the accompanying drawings, through out which like reference letters indicate corresponding parts in the various figures. The embodiments herein will be better understood from the following description with reference to the drawings, in which:

FIG. 1 is a flow chart of the SOC estimation logic, according to embodiments as disclosed herein;

FIG. 2 depicts a system in a vehicle for estimating SOC of a battery, according to embodiments as disclosed herein;

FIG. 3 is a flowchart depicting the process of estimating SOC_{OCV}, according to embodiments as disclosed herein;

FIG. 4 is a flowchart depicting the process of estimating SOC using Coulomb counting, according to embodiments as disclosed herein; and

FIG. 5 is a flow chart depicting the process of the determining the correction factor that is applied when coulomb counting is performed, according to embodiments as disclosed herein.

### DETAILED DESCRIPTION OF INVENTION

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

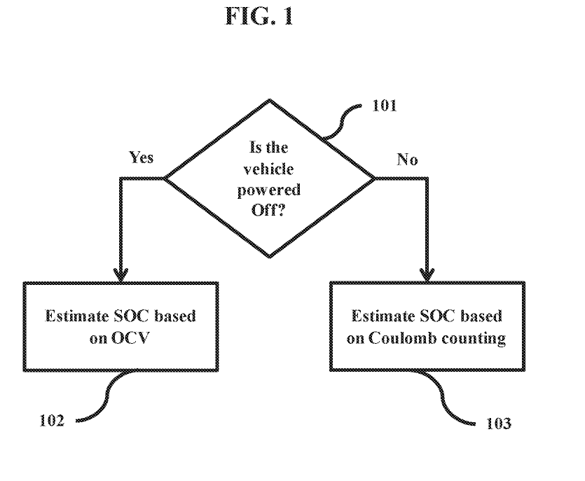

The embodiments herein provide methods and systems for determining State of Charge (SOC) of a lead acid battery in a vehicle. Referring now to the drawings, and more particularly to FIGS. 1 through 5, where similar reference characters denote corresponding features consistently throughout the figures, there are shown preferred embodiments.

The vehicle, as referred to herein can be any vehicle comprising of a lead acid battery. In an embodiment herein, the vehicle can be a hybrid vehicle. In an embodiment herein, the vehicle can comprise of only a conventional engine based powertrain. Example of the vehicle can be a car, truck, van, bus, and so on.

FIG. 1 is a flow chart of the SOC estimation logic. A check is made (101) if the vehicle has been powered off. If the vehicle has been powered off, the SOC (State of Charge) of a battery is estimated (102) based on OCV (Open Circuit Voltage) (hereinafter referred to as SOC_{OCV}). If the vehicle has not been powered off, the SOC of the battery is estimated (103) based on coulomb counting (hereinafter referred to as SOC_{EST}). The various actions in method 100 may be performed in the order presented, in a different order or simultaneously. Further, in some embodiments, some actions listed in FIG. 1 may be omitted.

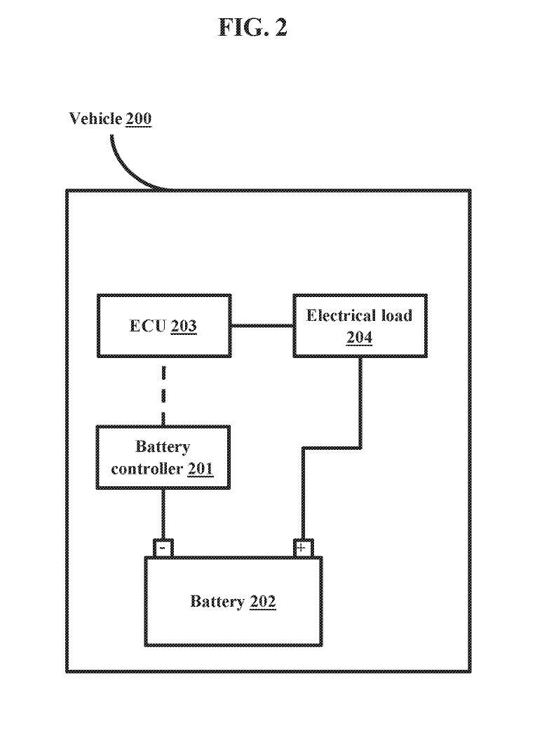

FIG. 2 depicts a system in a vehicle for estimating SOC of a battery. The system in the vehicle 200 comprises of a battery controller 201 mounted on a negative terminal of the battery 202. The battery controller 201 can be further connected to at least one Electronic Control Unit (ECU) 203 present in the vehicle and at least one electrical load 204 present in the vehicle 200.

The battery controller 201 can check if the vehicle 200 has been powered off. If the vehicle has been powered off, the battery controller 201 can estimate the SOC of the battery 202 is estimated (102) based on OCV. The battery controller 201 can generate a master OCV table by measuring the OCV of the battery 202, once the battery is full rested with no charge throughput, at pre-defined measurement intervals for a pre-defined time period (for example, every 30 minutes for a 4 hour duration). The master OCV table, comprising of a matrix with a pre-defined number of indices (for example, 8), is fully populated in the pre-defined time period. In an embodiment herein, the battery 202 achieves chemical, electrical and thermal equilibrium in the pre-defined time period. If battery is not rested for the pre-defined time period, but is in rest for more than the pre-defined measurement intervals, the battery controller 201 generates a running OCV table. The battery controller 201 can correct the running OCV table dynamically using a previous master OCV table (if present). The battery controller 201 determines the SOC_{OCV} based on the OCV table (which can be either the master OCV table or the running OCV table) for the current ignition cycle. If the battery is not rested for more than 30 minutes, the battery controller 201 can consider the SOC from the previous ignition cycle as the battery SOC.

If the vehicle 200 has not been powered off, the battery controller 201 can estimate the SOC of the battery 202 based on coulomb counting. Dynamic (run-time) energy throughput, also known as Coulomb Counter, is an integration of current over time (Ampere-second) and the battery controller 201 can be calculated using the charging rates, discharge rates and the battery temperature. The battery controller 201 can update the coulomb counter to a pre-defined level, if the battery charge current is saturated for a defined temperature to a pre-defined level. The battery controller 201 can perform dynamic charge and discharge correction using factors such as discharge and charge related efficiency on the overall system. With coulomb counter and correction factor, the battery controller 201 determines the SOC_{EST} for a current vehicle ignition cycle. The battery controller 201 applies battery-ageing factor, to accommodate capacity degradation, to the overall SOC calculation.

In an embodiment herein, the vehicle 200 comprises of a memory storage location, wherein the battery controller 201 can store data (such as the OCV values, master OCV table, estimated SOC, and so on) in the memory storage location. The battery controller 201 can also fetch data from the battery storage location, as and when required.

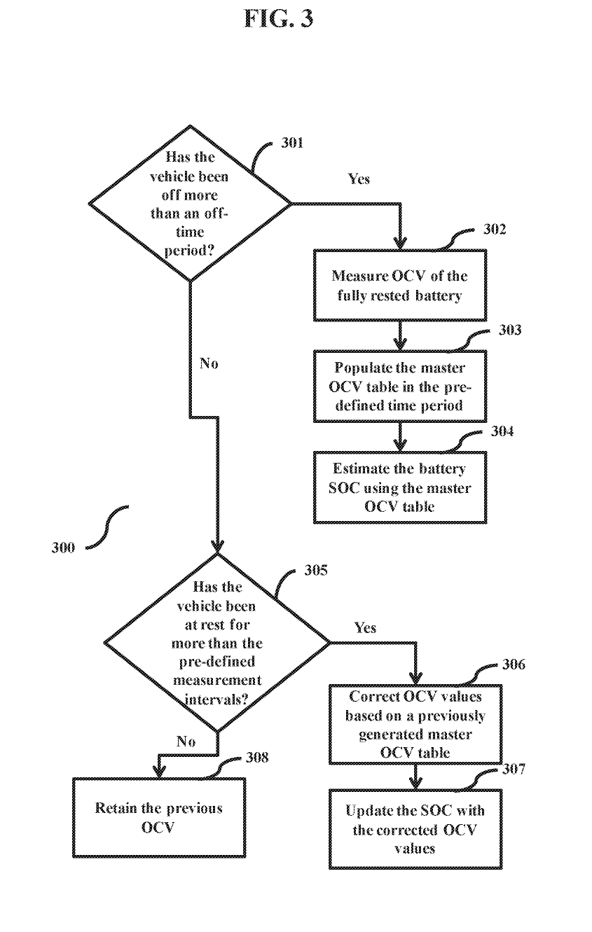

FIG. 3 is a flowchart depicting the process of estimating SOC_{OCV}. The battery controller 201 checks (301) for how much time the vehicle has been off. If the time elapsed is more than a pre-defined off-time period, the battery controller 201 measures (302) OCV of the fully rested battery 202, no charge throughput, at pre-defined measurement intervals for a pre-defined time period. Based on the measurements, the battery controller 201 populates (303) the master OCV table in the pre-defined time period, wherein the master OCV table comprises of a matrix with a pre-defined number of indices. In an example, the master OCV table, with 8 indices matrix, can be fully populated in 4 hours, which is the time in which the battery 202 achieves chemical, electrical and thermal equilibrium. The battery controller 201 estimates (304) the battery SOC using the master OCV table. The battery SOC can be estimated by mapping every value of the master OCV with the battery SOC. If the time elapsed is less than the pre-defined off-time per_{iod}, the battery controller 201 checks (305) if the vehicle 200 has been at rest for more than the pre-defined measurement intervals. If the vehicle 200 has been at rest for more than the pre-defined measurement intervals, the battery controller 201 corrects (306) OCV values based on a previously generated master OCV table (if available). The battery controller 201 can be configured to analyze the previously generated master OCV table to identify the values in the previously generated master OCV table corresponding to the pre-defined measurement intervals. The battery controller 201 further updates (307) the SOC with the corrected OCV values. The battery controller 201 can be configured identify the corrected OCV by correlating the difference between the measured currents OCV and the corresponding OCV from the previously generated master OCV table to updated the SOC with the corrected OCV values. If the vehicle 200 has been at rest for less than the pre-defined measurement intervals, the battery controller 201 retains (308) the previous OCV. The various actions in method 300 may be performed in the order presented, in a different order or simultaneously. Further, in some embodiments, some actions listed in FIG. 3 may be omitted.

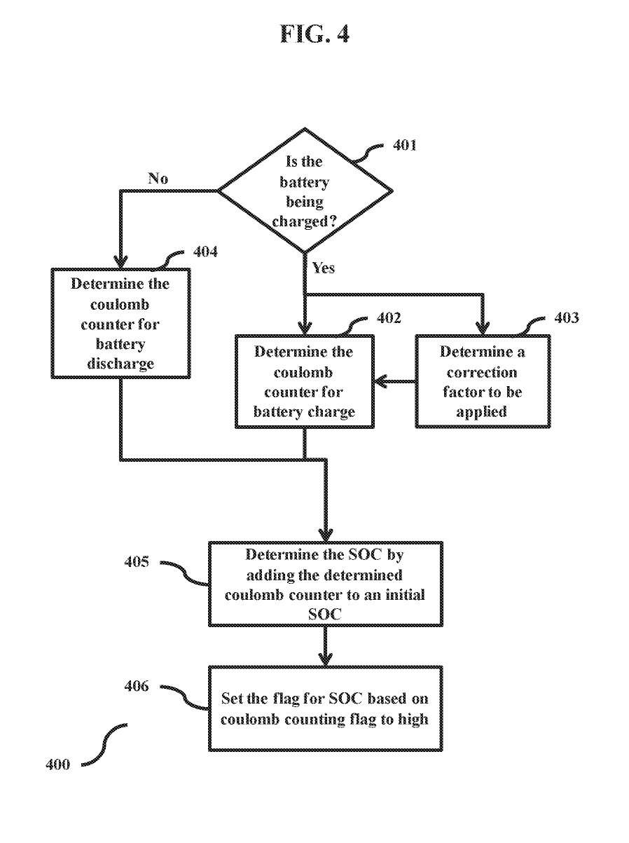

FIG. 4 is a flowchart depicting the process of estimating SOC using Coulomb counting. The battery controller 201 checks (401) if the battery 202 is currently being charged. In an embodiment herein, the battery controller 201 can check if the battery 202 is currently being charged by checking if the charging flag is active. If the battery 202 is currently being charged, the battery controller 201 determines (402) the coloumb counter for battery charge. The battery controller 201 can determine the coulomb counter for battery charge as follows:

Coulomb counting(charge)=I*(Ktc*Kcc)

### Wherein

I is the current throughput;
Ktc is the charging temperature factor; and
Kcc is the charge rate factor.

The battery controller 201 further determines (403) a correction factor that is applied to the SOC. If the battery 202 is currently not being charged, the battery controller 201 determines (404) the coloumb counter for battery discharge. The battery controller 201 can determine the coulomb counter as follows:

Coulomb counting(discharge)=I*(Ktd*Kdc)

### Wherein

Ktd is the discharging temperature factor; and
Kdc is the discharge rate factor.

The battery controller 201 determines (405) the SOC by adding the determined coulomb counter to an initial SOC, at pre-defined estimation time intervals and applying the correction factor. The initial SOC can depend on the previous state of the vehicle. If the vehicle 200 is starting after power off, the battery controller 201 can consider SOC_{OCV} as the initial SOC. If the vehicle 200 is not starting after power off, the battery controller 201 considers a previously estimated SOC using coulomb counting as the initial SOC. The battery controller 201 further sets (406) the flag for SOC based on coulomb counting flag to high. The various actions in method 400 may be performed in the order presented, in a different order or simultaneously. Further, in some embodiments, some actions listed in FIG. 4 may be omitted.

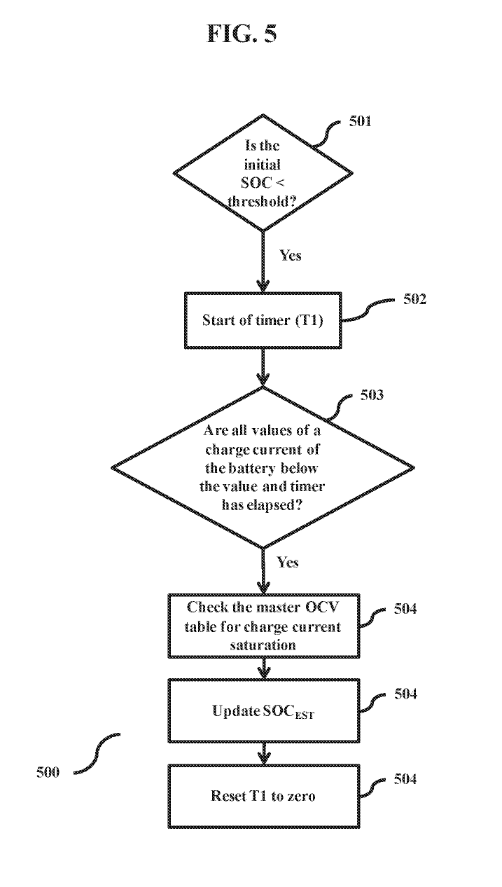

FIG. 5 is a flow chart depicting the process of the determining the correction factor that is applied when coulomb counting is performed. The battery controller 201 checks (501) if the initial SOC is less than a threshold. If the initial SOC is less than the threshold, the battery controller 201 starts (502) a timer T1. With the timer on, the battery controller 201 checks (503) if all values of a charge current of the battery 202 are below a pre-defined current threshold. If all values of the charge current of the battery 202 are below the pre-defined current threshold, the battery controller 201 then checks (504) the master OCV table for charge current saturation, based on the saturation current, and the battery temperature. The battery controller 201 resets (506) the timer to zero on every update (505) to the SOC_{EST}. The various actions in method 500 may be performed in the order presented, in a different order or simultaneously. Further, in some embodiments, some actions listed in FIG. 5 may be omitted.

The embodiments disclosed herein can be implemented through at least one software program running on at least one hardware device and performing network management functions to control the network elements. The network elements shown in FIG. 2, includes blocks which can be at least one of a hardware device, or a combination of hardware device and software module.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the embodiments as described herein.

We claim:

1. A system for monitoring SOC (State of Charge) of a lead-acid battery in a vehicle (200), the system comprising of a battery controller (201) configured for
estimating SOC of the battery using Open Circuit Voltage (OCV), if the vehicle (200) is powered off;
estimating SOC of the battery using coulomb counting, if the vehicle (200) is not powered off; and
wherein the battery controller (201) is connected to a negative lead of the lead-acid battery.

2. The system, as claimed in claim 1, wherein the battery controller (201) is configured for estimating SOC of the battery using OCV by
measuring OCV of the battery (202), no charge throughput, for a pre-defined time period at pre-defined measurement intervals, if the vehicle (200) has been off for more than a pre-defined time period;
populating a master OCV table with the measured OCV, wherein the master OCV table comprises of a matrix with a pre-defined number of indices; and
estimating battery SOC using the master OCV table.

3. The system, as claimed in claim 1, wherein the battery controller (201) is configured for estimating SOC of the battery using OCV by correcting OCV values based on a previously generated master OCV table, if the vehicle has not been off for more than the pre-defined off-time period.

4. The system, as claimed in claim 1, wherein the battery controller (201) is configured for estimating SOC of the battery using OCV by correcting OCV values based on a previously generated master OCV table, if the vehicle has not been off for more than the pre-defined off-time period and the vehicle has been off for less than the pre-defined measurement intervals.

5. The system, as claimed in claim 1, wherein the battery controller (201) is configured for estimating SOC of the battery using OCV by
determining coulomb counter for battery charge as the product of current throughput, a charging temperature factor and a charge rate factor, if a charging flag is active;
determining coulomb counter for battery discharge as the product of current throughput, a discharging temperature factor and a discharge rate factor, if the charging flag is not active;
determining SOC by adding the determined coulomb counter to an initial SOC.

6. The system, as claimed in claim 5, wherein the battery controller (201) is configured to determine the initial SOC depending on previous state of the vehicle (200).

7. The system, as claimed in claim 5, wherein the battery controller (201) is further configured to setting a flag for SOC based on coulomb counting flag to high.

8. The system, as claimed in claim 5, wherein the battery controller (201) is further configured to apply a correction factor to the determined SOC.

9. A method for monitoring SOC (State of Charge) of a lead-acid battery in a vehicle (200), the method comprising
estimating SOC of the battery using Open Circuit Voltage (OCV) by a battery controller (201), if the vehicle (200) is powered off; and
estimating SOC of the battery using coulomb counting by a battery controller (201) by the battery controller (201), if the vehicle (200) is not powered off;
wherein the battery controller (201) is connected to a negative lead of the lead-acid battery.

10. The method, as claimed in claim 9, wherein estimating SOC of the battery using OCV further comprises
measuring OCV of the battery (202) by the battery controller (201), no charge throughput, for a pre-defined time period at pre-defined measurement intervals, if the vehicle (200) has been off for more than a pre-defined time period;
populating a master OCV table with the measured OCV by the battery controller (201), wherein the master OCV table comprises of a matrix with a pre-defined number of indices; and
estimating battery SOC by the battery controller (201) using the master OCV table.

11. The method, as claimed in claim 9, wherein estimating SOC of the battery using OCV comprises correcting OCV values based on a previously generated master OCV table by the battery controller (201), if the vehicle has not been off for more than the pre-defined off-time period.

12. The method, as claimed in claim 9, wherein estimating SOC of the battery using OCV comprises correcting OCV values based on a previously generated master OCV table by the battery controller (201), if the vehicle has not been off for more than the pre-defined off-time period and the vehicle has been off for less than the pre-defined measurement intervals.

13. The method, as claimed in claim 9, wherein estimating SOC of the battery using OCV comprises
determining coulomb counter for battery charge as the product of current throughput by the battery controller (201), a charging temperature factor and a charge rate factor, if a charging flag is active;
determining coulomb counter for battery discharge as the product of current throughput by the battery controller (201), a discharging temperature factor and a discharge rate factor, if the charging flag is not active;
determining SOC by adding the determined coulomb counter to an initial SOC by the battery controller (201).

14. The method, as claimed in claim 13, wherein determining the initial SOC by the battery controller (201) depending on previous state of the vehicle (200).

15. The method, as claimed in claim 13, wherein the method further comprises setting a flag for SOC based on coulomb counting flag to high by the battery controller (201).

16. The method, as claimed in claim 13, wherein method further comprises applying a correction factor to the determined SOC by the battery controller (201).
